(19) United States
(12) Patent Application Publication
(10) Pub. No.: US 2007/0241441 A1
(43) Pub. Date: Oct. 18, 2007

(54) MULTICHIP PACKAGE SYSTEM

(75) Inventors: Sungwon Choi, Ichon-si (KR); Tae Sung Jeong, Ichon-si (KR)

Correspondence Address: ISHIMARU & ZAHRT LLP, 333 W. EL CAMINO REAL, SUITE 330, SUNNYVALE, CA, 94087, US

(73) Assignee: STATS ChipPAC Ltd., Singapore (SG)

(21) Appl. No.: 11/379,018

(22) Filed: Apr. 17, 2006

(51) Int. Cl. H01L 23/02

(52) U.S. Cl. 257/686

(57) ABSTRACT

A multichip package system is provided forming a first substrate having a first side, a second side, and a first opening, connecting a first integrated circuit die to the first substrate through the first opening, connecting a second integrated circuit die on the first substrate, and encapsulating the first integrated die and second integrated circuit die on the first substrate.

### TECHNICAL FIELD

The present invention relates generally to integrated circuit packages and more particularly to a stacked integrated circuit package system.

### BACKGROUND ART

Modern consumer electronics, such as smart phones, personal digital assistants, and location based services devices, as well as enterprise electronics, such as servers and storage arrays, are packing more integrated circuits into an ever shrinking physical space with expectations for decreasing cost. Numerous technologies have been developed to meet these requirements. Some of the research and development strategies focus on new package technologies while others focus on improving the existing and mature package technologies. Research and development in the existing package technologies may take a myriad of different directions.

One proven way to reduce cost is to use package technologies with existing manufacturing methods and equipments. Paradoxically, the reuse of existing manufacturing processes does not typically result in the reduction of package dimensions. Existing packaging technologies struggle to cost effectively meet the ever demanding integration of today's integrated circuits and packages.

In response to the demands for improved packaging, many innovative package designs have been conceived and brought to market. The multi-chip module has achieved a prominent role in reducing the board space. Numerous package approaches stack multiple integrated circuits, package level stacking, or package-on-package (POP). Known-good-die KGD and assembly process yields are not an issue since each package can be tested prior to assembly, allowing KGD to be used in assembling the stack. But stacking integrated devices, package-on-package, or a combination thereof have system level difficulties. Package-on-package structure is used for decreasing the assembly yield loss of package and convenience of testing assembled product. However, its height has increased because it was composed of two ordinary packages.

Thus, a need still remains for a stackable integrated circuit package system providing low cost manufacturing, improved yields, reduce the integrated circuit package dimensions and flexible stacking and integration configurations. In view of the ever-increasing need to save costs and improve efficiencies, it is more and more critical that answers be found to these problems.

Solutions to these problems have been long sought but prior developments have not taught or suggested any solutions and, thus, solutions to these problems have long eluded those skilled in the art.

### DISCLOSURE OF THE INVENTION

The present invention provides a multichip package system including forming a first substrate having a first side, a second side, and a first opening, connecting a first integrated circuit die to the first substrate through the first opening, connecting a second integrated circuit die on the first substrate, and encapsulating the first integrated die and second integrated circuit die on the first substrate.

Certain embodiments of the invention have other aspects in addition to or in place of those mentioned or obvious from the above. The aspects will become apparent to those skilled in the art from a reading of the following detailed description when taken with reference to the accompanying drawings.

### BRIEF DESCRIPTION OF THE DRAWINGS

FIG. 1 is a cross-sectional view of a first multichip package system in an embodiment of the present invention;

FIG. 2 is a cross-sectional view of a second multichip package system in an alternative embodiment of the present invention;

FIG. 3 is a cross-sectional view of a first integrated circuit package-on-package system having the first multichip package system;

FIG. 4 is a cross-sectional view of a second integrated circuit package-on-package system having the first multichip package system;

FIG. 5 is a cross-sectional view of a third integrated circuit package-on-package system having the second multichip package system; and

FIG. 6 is a flow chart of a multichip package system for manufacture of the multichip package system in an embodiment of the present invention.

### BEST MODE FOR CARRYING OUT THE INVENTION

In the following description, numerous specific details are given to provide a thorough understanding of the invention. However, it will be apparent that the invention may be practiced without these specific details. In order to avoid obscuring the present invention, some well-known system configurations, and process steps are not disclosed in detail. Likewise, the drawings showing embodiments of the apparatus are semi-diagrammatic and not to scale and, particularly, some of the dimensions are for the clarity of presentation and are shown greatly exaggerated in the figures. The same numbers are used in all the figures to relate to the same elements.

The term “horizontal” as used herein is defined as a plane parallel to the conventional integrated circuit surface, regardless of its orientation. The term “vertical” refers to a direction perpendicular to the horizontal as just defined. Terms, such as “above”, “below”, “bottom”, “top”, “side” (as in “sidewall”), “higher”, “lower”, “upper”, “over”, and “under”, are defined with respect to the horizontal plane. The term “on” means there is direct contact among elements.

The term “processing” as used herein includes deposition of material, patterning, exposure, development, etching, cleaning, molding, and/or removal of the material or as required in forming a described structure.

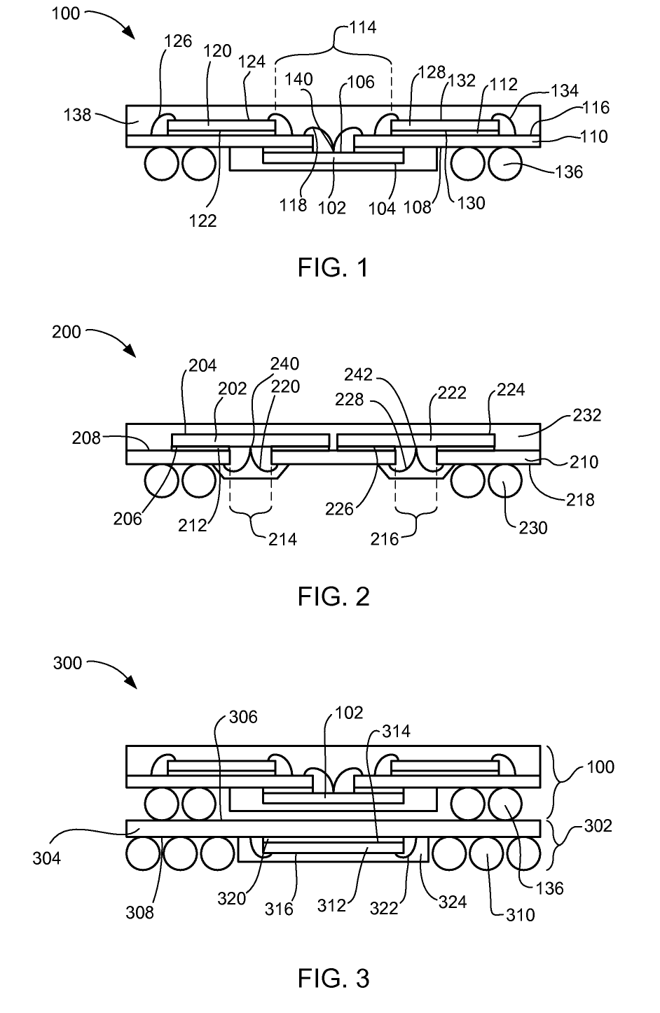

Referring now to FIG. 1, therein is shown a cross-sectional view of a first multichip package system 100 in an embodiment of the present invention. A first integrated circuit die 102 includes a first non-active side 104 and a first active side 106 having circuitry fabricated thereon. The first integrated circuit die 102 mounts on a first side 108, such as a bottom side, of a substrate 110, wherein the first active side 106 attaches to the substrate 110 with an adhesive 112. A central portion of the first active side 106 has bonding pads 140. The substrate 110 has an opening 114 for electrical connections between the first integrated circuit die 102 attached on the first side 108 and a second side 116, such as a top side, of the substrate 110. First interconnects 118, such as bond wires, electrically connect the bonding pads 140 and the second side 116 with a board-on-chip (BOC) configuration.

A second integrated circuit die 120 includes a second non-active side 122 and a second active side 124 with circuitry fabricated thereon. The second integrated circuit die 120 mounts on the second side 116, wherein the second non-active side 122 attaches to the substrate 110 with the adhesive 112. Second interconnects 126, such as bond wires, electrically connect the second integrated circuit die 120 and the second side 116 of the substrate 110. The location of the second integrated circuit die 120 is on one side of the opening 114 such that the opening 114 is not covered by the second integrated circuit die 120. Also, the connections of the first interconnects 118 to the second side 116 are not obstructed, and inadvertent crossing of the first interconnects 118 with the second interconnects 126 is minimized if not eliminated.

For illustrative purpose, the second integrated circuit die 120 is shown as a bond wire device, although it is understood that other type of devices with different electrical interconnect structures may be used, such as flip chip or fine pitch ball grid array (FBGA). Also for illustrative purpose, the second non-active side 122 is shown attached to the substrate 110, although it is understood that the second active side 124 may attach to the substrate 110 with the appropriate interconnect structure and device.

Similarly, a third integrated circuit die 128 includes a third non-active side 130 and a third active side 132 with circuitry fabricated thereon. The third integrated circuit die 128 mounts on the second side 116, wherein the third non-active side 130 attaches to the substrate 110 with the adhesive 112. Third interconnects 134, such as bond wires, electrically connect the third integrated circuit die 128 and the second side 116 of the substrate 110. The location of the third integrated circuit die 128 is on a side opposite the second integrated circuit die 120 of the opening 114 such that the opening 114 is not covered by the third integrated circuit die 128. Also, the connections of the first interconnects 118 to the second side 116 are not obstructed, and inadvertent crossing of the first interconnects 118 with the third interconnects 134 is minimized if not eliminated.

For illustrative purpose, the third integrated circuit die 128 is shown as a bond wire device, although it is understood that other type of devices with different electrical interconnect structures may be used, such as flip chip or fine pitch ball grid array (FBGA). Also for illustrative purpose, the third non-active side 130 is shown attached to the substrate 110, although it is understood that the third active side 132 may attach to the substrate 110 with the appropriate interconnect structure and device.

The substrate 110, as described above, has the first side 108 and the second side 116. Both sides have contact sites (not shown) for connections with the interconnect structures. The first side 108 and the second side 116 may have conductive traces (not shown) to route the electrical signals to and from the contacts sites. Electrical vias (not shown) may connect the conductive traces from the first side 108 and the second side 116 at appropriate locations. The substrate 110 may have an insulator layer (not shown) electrically isolating the conductive traces from the first side 108 and the second side 116. The first side 108 of the substrate 110 has external interconnects 136 attached thereon. The substrate 110 may be any number of layers and may be made from a number of materials, such as organic or inorganic.

A mold compound 138, such as an epoxy mold compound (EMC), encapsulates the first integrated circuit die 102, the second integrated circuit die 120, the third integrated circuit die 128, the first interconnects 118, the second interconnects 126, and the third interconnects 134 on the substrate 110. The mold compound 138 along the first side 108 forms a center gate mold covering the first integrated circuit die 102 such that the dimensions of the center gate mold does not impede the connections of the external interconnects 136 to the next system level (not shown), such as a printed circuit board). The opening 114 is substantially filled by the mold compound 138.

It has been discovered that the height, width, and length of a multichip package may be minimized with side by side configuration of multiple integrated circuit dice on one side, for example a top side, of the substrate with one or more integrated circuit dice on the other side, for example a bottom side, of the substrate. The bottom side integrated circuit dice and the corresponding encapsulation do not extend beyond the external interconnect such that existing space may be used for packing more integrated circuit content into the package without increasing the package height. With the bottom side integrated circuit dice using a BOC design, the bottom side integrated circuit dice are located between the top side integrated circuit dice, the width and length of the package is further reduced.

Referring now to FIG. 2, therein is shown a cross-sectional view of a second multichip package system 200 in an alternative embodiment of the present invention. A first integrated circuit die 202 includes a first non-active side 204 and a first active side 206 having circuitry fabricated thereon. The first integrated circuit die 202 mounts on a first side 208, such as a top side, of a substrate 210, wherein the first active side 206 attaches to the substrate 210 with an adhesive 212. A central portion of the first active side 206 has first bonding pads 240. The substrate 210 includes a first opening 214 and a second opening 216. The first opening 214 is used for electrical connections between the first integrated circuit die 202 attached on the first side 208 and a second side 218, such as a bottom side, of the substrate 210. First interconnects 220, such as bond wires, electrically connect the first bonding pads 240 and the second side 218 with a board-on-chip (BOC) configuration.

Similarly, a second integrated circuit die 222 includes a second non-active side 224 and a second active side 226 having circuitry fabricated thereon. The second integrated circuit die 222 mounts next to the first integrated circuit die 202 on the first side 208, such as a top side, of the substrate 210, wherein the second active side 226 attaches to the substrate 210 with the adhesive 212. A central portion of the second active side 226 has second bonding pads 242. The second opening 216 is used for electrical connections between the second integrated circuit die 222 attached on the first side 208 and the second side 218, such as a bottom side, of the substrate 210. Second interconnects 228, such as bond wires, electrically connect the second bonding pads 242 and the second side 218 with a board-on-chip (BOC) configuration.

The substrate 210, as described above, has the first side 208 and the second side 218. Both sides have contact sites (not shown) for connections with the interconnect structures. The first side 208 and the second side 218 may have conductive traces (not shown) to route the electrical signals to and from the contacts sites. Electrical vias (not shown) may connect the conductive traces from the first side 208 and the second side 218 at appropriate locations. The substrate 210 may have an insulator layer (not shown) electrically isolating the conductive traces from the first side 208 and the second side 218. The first side 208 of the substrate 210 has external interconnects 230 attached thereon. The substrate 210 may be any number of layers and may be made from a number of materials, such as organic or inorganic.

A mold compound 232, such as an epoxy mold compound (EMC), encapsulates the first integrated circuit die 202, the second integrated circuit die 222, the first interconnects 220, and the second interconnects 228 on the substrate 210. The mold compound 232 along the second side 218 forms a center gate mold covering the first interconnects 220 and the second interconnects 228 such that the dimensions of the center gate molds does not impede the connections of the external interconnects 230 to the next system level (not shown), such as a printed circuit board). The first opening 214 and the second opening 216 are substantially filled by the mold compound 232.

It has been discovered that the height, width, and length of a multichip package may be minimized with side by side configuration of multiple integrated circuit dice on one side, for example a top side, of a substrate and the electrical connections between integrated circuit dice to the substrate is to the other side, for example a bottom side, of the substrate. The bottom side electrical interconnects and the corresponding encapsulation do not extend beyond the external interconnects decreasing the package height.

Referring now to FIG. 3, therein is shown a cross-sectional view of a first integrated circuit package-on-package system 300 having the first multichip package system 100. The first multichip package system 100 mounts on a bottom package 302 forming a package-on-package structure. The bottom package 302 includes a bottom substrate 304 having a top side 306 and a bottom side 308. Both sides have contact sites (not shown) for connections with the interconnect structures. The external interconnects 136 of the first multichip package system 100 connect to the contact sites on the top side 306 of the bottom substrate 304.

The top side 306 and the bottom side 308 may have conductive traces (not shown) to route the electrical signals to and from the contacts sites. Electrical vias (not shown) may connect the conductive traces from the top side 306 and the bottom side 308 at appropriate locations. The bottom substrate 304 may have an insulator layer (not shown) electrically isolating the conductive traces from the top side 306 and the bottom side 308. The bottom side 308 of the bottom substrate 304 has bottom external interconnects 310 attached thereon. The bottom substrate 304 may be any number of layers and may be made from a number of materials, such as organic or inorganic materials.

An integrated circuit die 312 includes a non-active side 314 and an active side 316 having circuitry fabricated thereon. The integrated circuit die 312 mounts on the bottom side 308, wherein the non-active side 314 attaches to the bottom substrate 304 with an adhesive 320. Interconnects 322, such as bond wires, electrically connect the integrated circuit die 312 and the bottom side 308.

A mold compound 324, such as an epoxy mold compound (EMC), encapsulates the integrated circuit die 312 and the interconnects 322 on the bottom side 308 of the bottom substrate 304. The mold compound 324 forms a center gate mold without impeding the connections of the bottom external interconnects 310 to the next system level (not shown), such as a printed circuit board. The center gate mold of the first integrated circuit die 102 does not impact the height of the first integrated circuit package-on-package system 300 beyond the z-axis requirements of the external interconnects 136 of the first multichip package system 100.

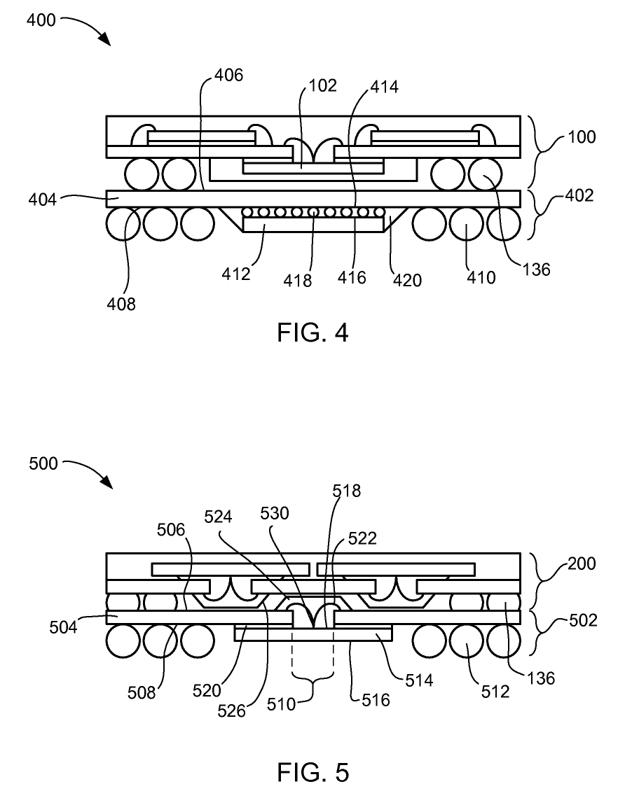

Referring now to FIG. 4, therein is shown a cross-sectional view of a second integrated circuit package-on-package system 400 having the first multichip package system 100. The first multichip package system 100 mounts on a bottom package 402 forming a package-on-package structure. The bottom package 402 includes a bottom substrate 404 having a top side 406 and a bottom side 408. Both sides have contact sites (not shown) for connections with the interconnect structures. The external interconnects 136 of the first multichip package system 100 connect to the contact sites on the top side 406 of the bottom substrate 404.

The top side 406 and the bottom side 408 may have conductive traces (not shown) to route the electrical signals to and from the contacts sites. Electrical vias (not shown) may connect the conductive traces from the top side 406 and the bottom side 408 at appropriate locations. The bottom substrate 404 may have an insulator layer (not shown) electrically isolating the conductive traces from the top side 406 and the bottom side 408. The bottom side 408 of the bottom substrate 404 has bottom external interconnects 410 attached thereon. The bottom substrate 404 may be any number of layers and may be made from a number of materials, such as organic or inorganic materials.

An integrated circuit die 412, such as a flip chip, includes a non-active side 414 and an active side 416 having circuitry and interconnects 418, such as solder bumps, fabricated thereon. The integrated circuit die 412 mounts on the bottom side 408, wherein the interconnects 418 attach to the bottom side 408.

A mold compound 420, such as an epoxy mold compound (EMC), encapsulates the interconnects 418 on the bottom side 408. The mold compound 420 also surrounds the integrated circuit die 412 with the non-active side 414 exposed and without impeding the connections of the bottom external interconnects 410 to the next system level (not shown), such as a printed circuit board). The mold compound 420 and the first integrated circuit die 102 does not impact the height of the second integrated circuit package-on-package system 400 beyond the z-axis requirements of the external interconnects 136 of the first multichip package system 100.

Referring now to FIG. 5, therein is shown a cross-sectional view of a third integrated circuit package-on-package system 500 having the second multichip package system 200. The second multichip package system 200 mounts on a bottom package 502 forming a package-on-package structure. The bottom package 502 includes a bottom substrate 504 having a top side 506, a bottom side 508, and an opening 510. Both sides have contact sites (not shown) for connections with the interconnect structures. The external interconnects 136 of the second multichip package system 200 connect to the contact sites on the top side 506 of the bottom substrate 504.

The top side 506 and the bottom side 508 may have conductive traces (not shown) to route the electrical signals to and from the contacts sites. Electrical vias (not shown) may connect the conductive traces from the top side 506 and the bottom side 508 at appropriate locations. The bottom substrate 504 may have an insulator layer (not shown) electrically isolating the conductive traces from the top side 506 and the bottom side 508. The bottom side 508 has bottom external interconnects 512 attached thereon. The bottom substrate 504 may be any number of layers and may be made from a number of materials, such as organic or inorganic materials.

An integrated circuit die 514 includes a non-active side 516 and an active side 518 having circuitry fabricated thereon. The integrated circuit die 514 mounts on the bottom side 508 of the bottom substrate 504, wherein the active side 518 attaches to the bottom side 508 with an adhesive 520. A central portion of the active side 518 has third bonding pads 530. The opening 510 is used for electrical connections between the integrated circuit die 514 on the bottom side 508 and the top side 506. Interconnects 522, such as bond wires, electrically connect the third bonding pads 530 and the top side 506 with a board-on-chip (BOC) configuration.

A mold compound 524, such as an epoxy mold compound (EMC), encapsulates the interconnects 522 on the top side 506 and fills the opening 510. The mold compound 524 forms a structure that fits in a recess 526 between the center gate molds of the second multichip package system 200 without impeding the connections of the external interconnects 136 on the top side 506. The integrated circuit die 514 does not impact the height of the bottom package 502 beyond the z-axis requirements of the bottom external interconnects 512.

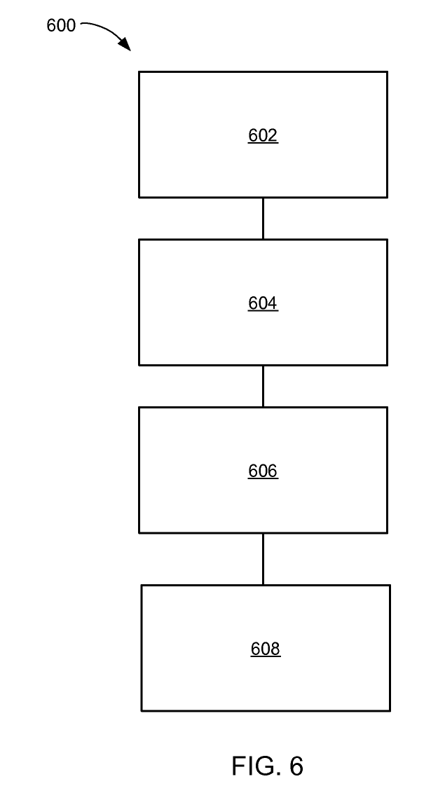

Referring now to FIG. 6, therein is shown a flow chart of a multichip package system 600 for manufacture of the multichip package system 100 in an embodiment of the present invention. The system 600 includes forming a first substrate having a first side, a second side, and a first opening in a block 602; connecting a first integrated circuit die to the first substrate through the first opening in a block 604; connecting a second integrated circuit die on the first substrate in a block 606; and encapsulating the first integrated die and second integrated circuit die on the first substrate in a block 608.

It has been discovered that the present invention thus has numerous aspects.

It has been discovered that the height, width, and length of a multichip package may be minimized with side by side configuration of multiple integrated circuit dice on one side, for example a top side, of the substrate with one or more integrated circuit dice on the other side, for example a bottom side, of the substrate. The bottom side integrated circuit dice and the corresponding encapsulation do not extend beyond the external interconnect such that existing space may be used for packing more integrated circuit content into the package without increasing the package height. With the bottom side integrated circuit dice using a BOC design, the bottom side integrated circuit dice are located between the top side integrated circuit dice, the width and length of the package is further reduced.

It has been also discovered that the height, width, and length of a multichip package may be minimized with side by side configuration of multiple integrated circuit dice on one side, for example a top side, of the substrate and the electrical connections between integrated circuit dice to the substrate is to the other side, for example a bottom side, of the substrate. The bottom side electrical interconnects and the corresponding encapsulation do not extend beyond the external interconnects decreasing the package height.

An aspect is that the present invention is the design of board on chip (BOC) package for utilizing the space of bottom side of one package. In the top of the package, separated single die instead of stacked die is used to avoid increasing top thickness. This modified package structure is capable of decreasing whole package thickness and it can also be utilized for more space by facing any package structures such as BOC, FBGA and Flip-chip.

Another aspect of the present invention is that the modified BOC design package improves practical use by facing top package that has top-sided and bottom-sided structures toward one single bottom package in a package-on-package configuration. Its structure can also be used with flip-chip package for bottom side package.

Yet another aspect of the present invention is that the modified BOC design package improves practical use by applying to two BOC designs in a package-on-package configuration.

Yet another important aspect of the present invention is that it valuably supports and services the historical trend of reducing costs and increasing performance. These and other valuable aspects of the present invention consequently further the state of the technology to at least the next level.

Thus, it has been discovered that the multichip package system method of the present invention furnishes important and heretofore unknown and unavailable solutions, capabilities, and functional aspects for increasing chip density while minimizing the space required in systems. The resulting processes and configurations are straightforward, cost-effective, uncomplicated, highly versatile and effective, can be implemented by adapting known technologies, and are thus readily suited for efficiently and economically manufacturing stacked integrated circuit packaged devices.

While the invention has been described in conjunction with a specific best mode, it is to be understood that many alternatives, modifications, and variations will be apparent to those skilled in the art in light of the aforegoing description. Accordingly, it is intended to embrace all such alternatives, modifications, and variations that fall within the scope of the included claims. All matters hithertofore set forth herein or shown in the accompanying drawings are to be interpreted in an illustrative and non-limiting sense.

The invention claimed is:

1. A multichip package system comprising:
forming a first substrate having a first side, a second side, and a first opening;
connecting a first integrated circuit die to the first substrate through the first opening;
connecting a second integrated circuit die on the first substrate; and
encapsulating the first integrated die and second integrated circuit die on the first substrate.

2. The system as claimed in claim 1 wherein:
connecting the first integrated circuit die to the first substrate through the first opening comprises:
attaching an active side of the first integrated circuit die on the first side, and
connecting an interconnect between the active side and the second side;
connecting the second integrated circuit die further comprises:
mounting the second integrated circuit die on the second side at one side of the first opening; and
further comprising:
mounting a third integrated circuit die on the second side at an opposite side of the first opening; and
encapsulating the interconnect.

3. The system as claimed in claim 1 further comprising:
forming the first substrate with a second opening;
attaching a first active side of the first integrated circuit die on the first side;
connecting a first interconnect between the first active side and the second side;
attaching a second active side of the second integrated circuit die on the first side;
connecting a second interconnect between the second active side and the second side through the second opening; and
encapsulating the first interconnect and the second interconnect.

4. The system as claimed in claim 1 wherein:
connecting the first integrated circuit die comprises:
connecting the first integrated circuit die on the first side, and
attaching an external interconnect on the first side; and
further comprising:
forming a bottom integrated circuit package having a second substrate;
attaching an integrated circuit die on a bottom side of the second substrate; and
attaching the external interconnect on a top side of the second substrate.

5. The system as claimed in claim 1 wherein:
connecting the first integrated circuit die comprises:
connecting the first integrated circuit die on the first side; and
further comprising:
attaching an external interconnect on the second side;
forming a bottom integrated circuit package having a second substrate with an opening;
connecting an integrated circuit die on a bottom side of the second substrate to a top side of the second substrate through the opening; and
attaching the external interconnect on the top side.

6. A multichip package system comprising:
forming a first substrate having a first side, a second side, and a first opening;
connecting a first integrated circuit die on the first side to the second side through the first opening;
connecting a second integrated circuit die on the first substrate; and
encapsulating the first integrated die and second integrated circuit die on the first substrate.

7. The system as claimed in claim 6 wherein connecting the first integrated circuit die comprises attaching the first integrated circuit die having an active side on the first side with an adhesive.

8. The system as claimed in claim 6 wherein connecting the first integrated circuit die comprises:
forming a bonding pad in a central region of an active side of the first integrated circuit die; and
connecting the bonding pad to the second side.

9. The system as claimed in claim 6 wherein connecting the second integrated circuit die comprises:
forming a bonding pad in a central region of an active side of the second integrated circuit die; and
connecting the bonding pad to the second side.

10. The system as claimed in claim 6 wherein encapsulating includes filling the first opening.

11. A multichip package system comprising:
a first substrate having a first side, a second side, and a first opening;
a first integrated circuit die connected to the first substrate through the first opening;
a second integrated circuit die on the first substrate; and
a mold compound to cover the first integrated die and second integrated circuit die on the first substrate.

12. The system as claimed in claim 11 wherein:
the first integrated circuit die to the first substrate through the first opening comprises:
an active side of the first integrated circuit die on the first side, and
an interconnect between the active side and the second side;
the second integrated circuit die further comprises:
the second integrated circuit die on the second side at one side of the first opening; and
further comprising:
a third integrated circuit die on the second side at an opposite side of the first opening; and
the mold compound to cover the interconnect.

13. The system as claimed in claim 11 further comprising:
the first substrate have a second opening;
a first active side of the first integrated circuit die on the first side;
a first interconnect between the first active side and the second side;
a second active side of the second integrated circuit die on the first side;
a second interconnect between the second active side and the second side through the second opening; and
the mold compound to cover the first interconnect and the second interconnect.

14. The system as claimed in claim 11 wherein:
the first integrated circuit die comprises:
the first integrated circuit die on the first side, and
an external interconnect on the first side; and
further comprising:
a bottom integrated circuit package having a second substrate;
an integrated circuit die on a bottom side of the second substrate; and
the external interconnect on a top side of the second substrate.

15. The system as claimed in claim 11 wherein:
the first integrated circuit die comprises:
the first integrated circuit die on the first side; and
further comprising:
an external interconnect on the second side;
a bottom integrated circuit package having a second substrate with an opening;
an integrated circuit die on a bottom side of the second substrate connected to a top side of the second substrate through the opening; and
the external interconnect on the top side.

16. The system as claimed in claim 11 wherein:
the first substrate having the first side, the second side, and the first opening provides signal routing;
the first integrated circuit die is on the first side and connected to the second side through the first opening;
the second integrated circuit die on the first substrate is electrically connected to the first substrate; and
the mold compound to cover the first integrated die and second integrated circuit die on the first substrate is an epoxy mold compound.

17. The system as claimed in claim 16 wherein the first integrated circuit die on the first side is attached to the first side with an adhesive.

18. The system as claimed in claim 16 wherein the first integrated circuit die on the first side comprises:
a bonding pad in a central region of an active side of the first integrated circuit die; and
the bonding pad connected to the second side.

19. The system as claimed in claim 16 wherein the second integrated circuit die on the first substrate comprises:
a bonding pad in a central region of an active side of the second integrated circuit die; and
the bonding pad connected to the second side.

20. The system as claimed in claim 16 wherein the mold compound fills the first opening.
